(19) United States
(12) Patent Application Publication
(10) Pub. No.: US 2007/0059846 A1
(43) Pub. Date: Mar. 15, 2007

(54) Manufacturing method for semiconductor memory

(76) Inventors: Yasutaka Kobayashi, Tokyo (JP); Daisuke Inomata, Tokyo (JP)

Correspondence Address: VOLENTINE FRANCOS, & WHITT PLLC, ONE FREEDOM SQUARE, 11951 FREEDOM DRIVE SUITE 1260, RESTON, VA, 20190, US

(21) Appl. No.: 11/368,424

(22) Filed: Mar. 7, 2006

(30) Foreign Application Priority Data
Sep. 9, 2005 (JP) 2005-262540

(51) Int. Cl. H01L 21/00; H01L 21/8242

(52) U.S. Cl. 438/3; 438/240; 257/E21.664

(57) ABSTRACT

A semiconductor memory is fabricated in the following manner. A tungsten plug is formed by burying metal material such as W into a contact hole formed in an inter-layer insulation film. Then, the inter-layer insulation film is etched back by a predetermined thickness so that the upper end portion of the tungsten plug protrudes. The Pt film, a ferroelectric film and another Pt film, which constitute the ferroelectric capacitor, are sequentially formed thereon. The Pt film, ferroelectric film and Pt film are patterned by batch etching, so as to form the ferroelectric capacitor having the ferroelectric film sandwiched by the platinum electrodes.

### BACKGROUND OF THE INVENTION

1. Field of the Invention

The present invention relates to a manufacturing method for a semiconductor memory, and more particularly to a method of manufacturing a semiconductor memory having a ferroelectric capacitor.

2. Description of the Related Art

One example of semiconductor memories using a ferroelectric capacitor is disclosed in Japanese Patent Application Kokai (Laid-Open) No. 2003-92389.

FIG. 2 of the accompanying drawings is a cross-sectional view of a conventional ferroelectric memory disclosed in Japanese Patent Application Kokai No. 2003-92389.

In this ferroelectric memory, an element isolation insulation film (i.e., field region) 2 is formed by the LOCOS (Local Oxidation of Silicon) method on the surface of the silicon substrate 1, and diffusion layers 7 are formed at a predetermined interval on the active region surrounded by the element isolation insulation film 2. The diffusion layer 7 will become a source-drain region of the transistor. On the channel region positioned between the diffusion layers 7, a gate electrode with a polycide structure, which is made of the polysilicon film 4 and WSi film 5, is formed via the gate oxide film 3. The side wall insulation film 6 is formed on the side wall of the gate electrode.

The inter-layer insulation film 8 is formed so as to cover the entire surface, and the contact holes 8a and 8b are formed in this inter-layer insulation film 8 within the regions of the diffusion layers 7. A barrier film 9 is formed in each of the contact holes 8a and 8b, and a tungsten plug 10 is embedded inside the barrier film 9. The barrier film 9 includes a Ti film that is a lower layer and a TiN film that is an upper layer. The barrier film 9 controls the reaction between Si of the silicon substrate l and W of the tungsten plug 10.

The barrier film 9 and the tungsten plug 10 protrude up from the top face of the inter-layer insulation film 8, and cover some of the top surface of the inter-layer insulation film 8. In other words, the tungsten plug 10 is formed to be a T-shape in the cross-section, and the area of the head part is larger than the area of the pillar part embedded in the inter-layer insulation film 8. An IrSiN film 23a is formed so as to cover the top face and the side face of a portion of the tungsten plug 10 and the barrier film 9 protruding from the inter-layer insulation film 8. The IrSiN film 23a extends for a predetermined length along the top face of the inter-layer insulation film 8. The IrSiN film 23a servers as the bottom electrode of the ferroelectric capacitor.

The SBT (SrBi₂Ta₂O₉) film 24 is formed so as to cover the top face and the side face of the IrSiN film 23a. The SBT film 24 serves as a ferroelectric film. A Pt film 25 is formed so as to cover the top face and a part of the side face of the SBT film 24. The Pt film 25 servers as the top electrode.

The IrSiN film 23b serves as the pad layer, and covers the protruding top face and side face of the tungsten plug 10 positioned at the center in FIG. 2. The inter-layer insulation film 16 is a silicon oxide film, and covers the entire surface. A contact hole 16a, which reaches the IrSiN film 23b, is formed at the center section of the inter-layer insulation film 16. A barrier film 17 is formed in the contact hole 16a. The barrier film 17 has the same configuration as the barrier film 9. The barrier film 17 contacts the IrSiN film 23b, and extends along the inner wall of the contact hole 16h and the top face of the inter-layer insulation film 16. A metal inter-connect layer 18, made of Al—Si—Cu, is formed on the barrier film 17.

Now the manufacturing method for this ferroelectric memory will be described.

First the element isolation insulation film 2 and the diffusion layers 7 are formed on the surface of the silicon substrate 1. The gate electrode, which includes the polysilicon film 4 and the WSi film 5, is formed on the channel region via the gate oxide film 3. The side wall insulation film 6 is formed on the side face of the gate electrode.

Then the inter-layer insulation film 8, which is a silicon oxide film, is formed so as to cover the entire surface. The contact holes 8a and 8b, which reach the associated diffusion layers 7 respectively, are formed in the inter-layer insulation film 8. The barrier film 9 is formed such that the barrier film 9 contacts the diffusion layer 7 in the associated contact hole 8a (8b), and extends along the inner walls of the contact hole 8a (8b) and the top face of the inter-layer insulation film 8.

Then the tungsten film is formed to fill the contact holes 8a and 8b and to extend over the inter-layer insulation film 8. This tungsten film is partly removed by etching so that the thickness of the tungsten film on the inter-layer insulation film 8 has a predetermined value. Then using photolithography technology and dry etching technology, the tungsten film and the barrier film 9 are patterned so that the barrier film 9 and the tungsten plug 10, of which cross-section are T-shaped as shown in FIG. 2, are formed.

After forming the IrSiN film to cover the entire face, this IrSiN film is patterned by photolithography technology and etching technology using a Cl₂/Ar type gas, so as to form the IrSiN film 23 with the shape shown in FIG. 2.

Then using the zol-gel method, the SBT film, which is a ferroelectric film, is formed on the entire face, and a Pt film, which serves as the top electrode, is formed on the surface of the SBT film. The SBT film and the Pt film are patterned using a photolithography technology and an etching technology, and the SBT film 24 and the Pt film 25 with the shape shown in FIG. 2 are formed. Then O₂ annealing is performed under high temperature conditions so that the defects of the SBT film 24 generated by etching are recovered, and the ferroelectric capacitor characteristics are improved.

The inter-layer insulation film 16, which is a silicon oxide film covering the entire face, is formed as shown in FIG. 2. Then, the contact hole 16a is formed. The barrier film 17 is formed so as to contact the IrSiN film 23b constituting the pad layer in the contact hole 16a, and to extend on the inner face of the contact hole 16a and on the top face of the inter-layer insulation film 16. After the metal wiring layer 18 is formed on the barrier film 17, the metal wiring layer 18 and the barrier layer 17 are patterned to be a predetermined shape, so as to obtain the ferroelectric memory shown in FIG. 2.

In this ferroelectric memory, the tungsten plug 10 is formed in a T-shape, protruding up from the top face of the inter-layer insulation film 8, and the IrSiN film (lower electrode) 23 is formed so as to cover the top face and the side face of this T-shaped tungsten plug 10. The SBT film 24 is formed so as to cover the top face and the side face of the IrSiN film 23. Thus, the effective area of the capacitor is increased, and sufficient capacitance can be secured for the capacitor. Consequently, even if the capacitor is miniaturized, the written data can be read with certainty.

The above ferroelectric memory, however, has the following problems.

Many masks for exposure are required since photolithography technology is frequently used. Also highly advanced precision is demanded for the alignment of masks, since the patterning of the protruding portion of the tungsten plug 10 is required. Because the protruding portion of the tungsten plug 10 is formed by patterning, the width of the protruding portion must be wider than the plug diameter in order to secure the margins of the alignment. Therefore the size of the capacitor cannot be decreased to be smaller than the width of the protruding portion of the plug.

In addition, this ferroelectric memory has a step difference in the contact connection section. As mentioned in International Symposium on Integrated Ferroelectrics 2005, “Novel BC Plug Technology for Highly Reliable Mass Productive 0.18 μm 1T1C COB Embedded FRAM”, this step difference portion may adversely affect the electric characteristics of the capacitor.

### SUMMARY OF THE INVENTION

It is one object of the present invention to manufacture a ferroelectric capacitor with good precision by simple processing steps.

According to one aspect of the present invention, there is provided a manufacturing method for a semiconductor memory of which storage element is a ferroelectric capacitor. The manufacturing method includes forming at least one circuit other than the storage element on a substrate, and forming an inter-layer insulation film over the circuit(s). The manufacturing method also includes forming a contact hole in the inter-layer insulation film such that the contact hole penetrates the inter-layer insulation-film and reaches the circuit formed on the substrate. The location of the contact hole is where the storage element will be formed on the inter-layer insulation film. The manufacturing method also includes forming a metal plug for inter-layer connection by feeding a metal material into the contact hole. The manufacturing method also includes removing a surface of the inter-layer insulation film by a predetermined thickness by, for example, etching so that an upper end portion of the metal plug protrudes from the surface of the inter-layer insulation film by a predetermined length. The manufacturing method also includes forming a first metal film on the entire surface of the inter-layer insulation film and the metal plug protruding from the inter-layer insulation film. The first metal film will become a lower (bottom) electrode of the ferroelectric capacitor. The manufacturing method also includes forming a ferroelectric film on the surface of the first metal film. The ferroelectric film will become a dielectric of the ferroelectric capacitor. The manufacturing method also includes forming a second metal film on the surface of the ferroelectric film. The second metal film will become an upper (top) electrode of the ferroelectric capacitor. The manufacturing method also includes forming the ferroelectric capacitor by patterning the second metal film, the ferroelectric film and the first metal film by batch etching.

After forming the metal plug by filling the contact hole of the inter-layer insulation film with the metal material, the upper end portion of the metal plug is made to protrude by etching back the inter-layer insulation film by a predetermined thickness. Then, the first metal film, the ferroelectric film and the second metal film, which constitute the ferroelectric capacitor, are formed thereon. The ferroelectric capacitor is formed by patterning the first metal film, ferroelectric film and second metal film by batch etching. Thus, it is possible to fabricate a ferroelectric capacitor with good precision by simple processing steps.

These and other objects, aspects, and advantages of the present invention will be more completely understood by reading the following description of the embodiment(s) with reference to the accompanying drawings. The drawings, however, are principally for description, and shall not limit the scope of the present invention.

### BRIEF DESCRIPTION OF THE DRAWINGS

FIG. 1 is a cross-sectional view of a ferroelectric memory according to an embodiment of the present invention;

FIG. 2 is a cross-sectional view of a conventional ferroelectric memory; and

FIG. 3A to FIG. 3E are diagrams depicting the steps of the manufacturing method for the ferroelectric capacitor shown in FIG. 1.

### DESCRIPTION OF THE INVENTION

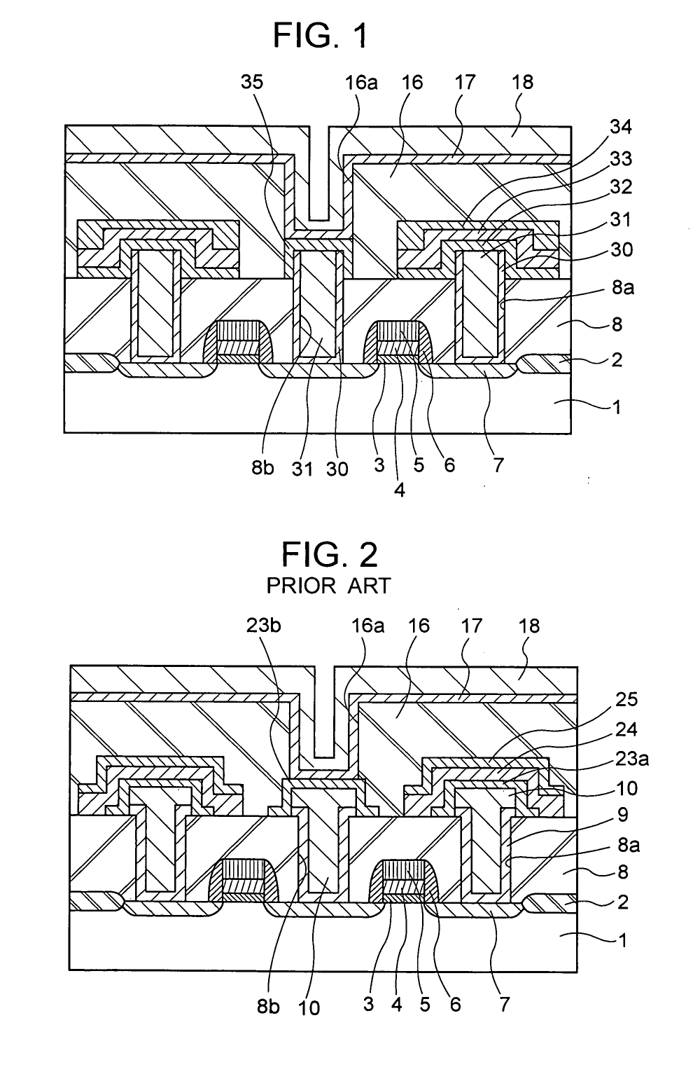

In FIG. 1 and FIG. 2, same elements are assigned the same reference symbols.

In the ferroelectric memory, an element isolation insulation film 2, constituting a field region, is formed on the surface of the silicon substrate 1 by the LOCOS method, and the diffusion layers 7, to be a source-drain region of the transistor, are formed at a predetermined interval in an active region enclosed by the element isolation insulation film 2. In a channel region positioned between the diffusion layers 7, a gate electrode with a polycide structure, which is a layered combination of polysilicon film 4 and WSi film 5, is formed via a gate oxide film 3. A side wall insulation film 6 is formed on the side wall of the gate electrode.

An inter-layer insulation film 8 is formed so as to cover the entire face, and contact holes 8a and 8b are formed in regions, positioned on the diffusion layers 7, in the inter-layer insulation film 8. In each of the contact holes 8a and 8b, a contact layer 30, which is about a 10 nm thick TiN film, is formed. About 500 to 1000 nm thick tungsten plug 31 is embedded inside each contact layer 30. The contact layer 30 improves the contact with the silicon substrate 1, and suppresses the reaction of the Si of the silicon substrate with the W of the tungsten plug 31. The upper end portions of the contact layer 30 and tungsten plug 31 are formed so as to protrude from the inter-layer insulation film 8.

A platinum electrode 32 having about 100 nm thickness is formed on the inter-layer insulation film 8 so as to cover the top face and the side face of the protruding contact film 30 and tungsten plug 31. The platinum electrode 32 also extends along the top face of the inter-layer insulation film 8 for a predetermined length. The platinum electrode 32 constitutes the bottom (lower) electrode of the ferroelectric capacitor.

A ferroelectric film 33 having about 100 nm thickness is formed so as to cover the top face and the side face of the platinum electrode 32. About 100 nm thick platinum electrode, constituting the top (upper) electrode of the ferroelectric capacitor, is formed so as to cover the top face and the side face of the ferroelectric film 33.

About 100 nm thick pad layer 35 of Pt is formed at the center in FIG. 1 so as to cover the top face and the side face of the protruding contact layer 30 and tungsten plug 31. The inter-layer insulation film 16, which is a silicon oxide film, is formed so as to cover the entire face, and the contact hole 16a, which reaches the pad layer 35, is formed in the center part of the inter-layer insulation film 16. In the contact hole 16a, the barrier film 17, having the same configuration as the contact layer 30, is formed so as to contact the pad layer 35 and to extend along the inner wall of the contact hole 16a and the top face of the inter-layer insulation film 16. The metal inter-connect layer 18, which is made of Al—Si—Cu, is formed on the barrier film 17.

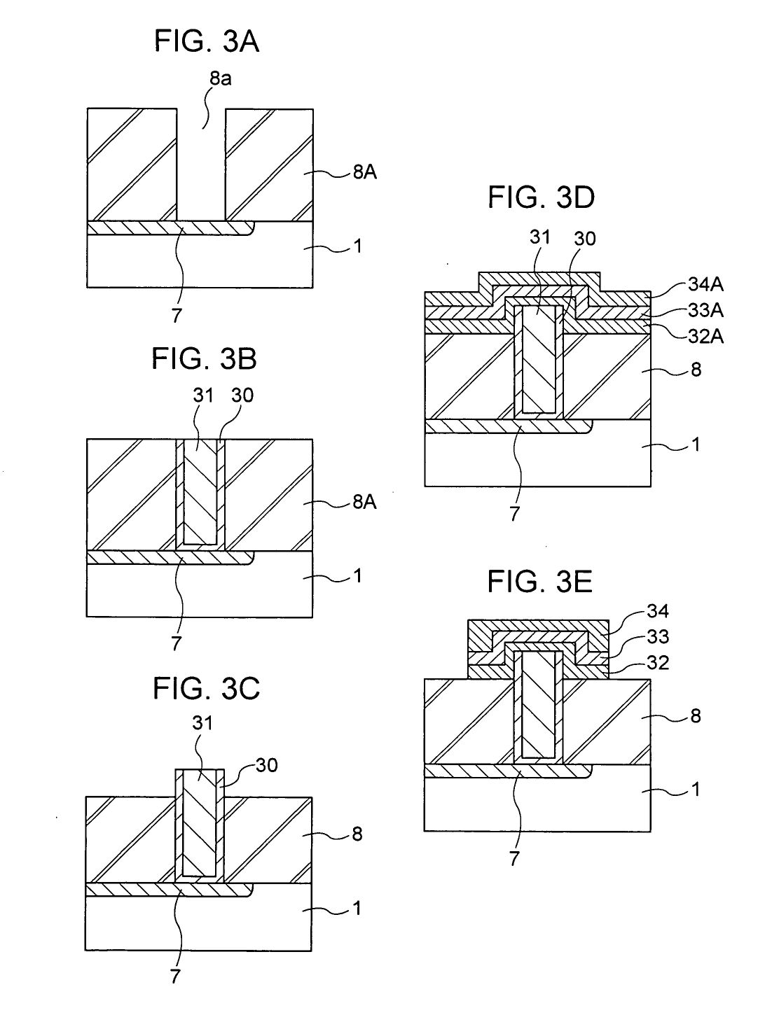

FIG. 3A to FIG. 3E are diagrams depicting the processing steps of the manufacturing method for the ferroelectric capacitor shown in FIG. 1. The manufacturing method for the ferroelectric capacitor will now be described with reference to FIG. 3A to FIG. 3E.

(1) Step 1

As FIG. 3A shows, on the silicon substrate 1 on which such elements as a transistor (not illustrated in FIG. 3A to FIG. 3E) are formed, the inter-layer insulation film 8A, for insulation from other elements, is formed to be a 500 to 1000 nm thickness. In this inter-layer insulation film 8A, a contact hole 8a for connecting with the corresponding diffusion layer 7 of the silicon substrate 1 is opened using standard photolithography technology and etching technology.

(2) Step 2

As FIG. 3B shows, about a 10 to 50 nm thick TiN and about a 500 to 1000 nm thick W are sequentially layered and buried in the contact hole 8a by the CVD (Chemical Vapor Deposition) method. TiN and W which overflow on the inter-layer insulation film 8A are removed by etching the entire face. Thus, the tungsten plug 31, which is enclosed by the contact layer 30 and is completely buried in the inter-layer insulation film 8A, is formed.

(3) Step 3

As FIG. 3C shows, the inter-layer insulation film 8A is partly removed by etching back using the contact layer 30 and the tungsten plug 31 as etching masks, so that upper parts of the contact layer 30 and the tungsten plug 31 are processed to be a column shape. It should be noted that the contact hole is normally processed to have the finished diameter within a 10 to 30% tolerance range. Thus, it is preferable that the thickness of the inter-layer insulation film 8A, to be removed by etching back, is set to be half the diameter of the contact hole 8a or more, and the tungsten plug 31 has a column shape protruding at the center. By removing the surface of the inter-layer insulation film 8A by etching back, the inter-layer insulation film 8 with a predetermined thickness is prepared.

(4) Step 4

As FIG. 3D shows, the Pt film 32A, constituting the lower electrode of the ferroelectric capacitor, the ferroelectric film 33A and the Pt film 34A, constituting the upper electrode, are sequentially formed to be about a 100 nm thickness respectively by the CVD method.

(5) Step 5

As FIG. 3E shows, the Pt film 32A, ferroelectric film 33A and Pt film 34A are patterned in batch by standard photolithography technology and etching technology. Thus, the ferroelectric capacitor that includes the ferroelectric film 33 sandwiched by predetermined dimensions of the platinum electrodes 32 and 34 is created.

The process subsequent to Step 5 is similar to the prior art. Specifically, the inter-layer insulation film 16, which is a silicon oxide film covering the entire face, is formed, and the contact hole 16a is formed. The barrier film 17 is formed so as to extend onto the inner wall of the contact hole 16a and the top face of the inter-layer insulation film 16. After forming the metal wiring layer 18 on the barrier layer 17, the metal wiring layer 18 and the barrier film 17 are patterned to be a predetermined shape.

The manufacturing method for a semiconductor memory of the present embodiment has the following advantages.

(a) Since the patterning of the entire ferroelectric capacitor, which is the core part of the semiconductor memory, is performed by batch processing from the top electrode, adding only one layer as the mask layer is required.

(b) The ferroelectric capacitor and the tungsten plug 31 are aligned by self alignment only in the film formation process, so that actual alignment process is unnecessary, and patterning with very high precision is possible. As a result, improvement of the processing yield in ferroelectric capacitor fabrication can be expected.

(c) The protruding portion of the tungsten plug 31 has the same diameter as the remaining portion of the tungsten plug 31, so that the ferroelectric capacitor can be miniaturized easily.

(d) In terms of securing a stable operation of the memory in the miniaturization of elements, the size of the capacitance of the capacitor for storing charges determines the quality, so that it is critical to increase the area by making the capacitor a three-dimensional shape. In the case of ferroelectric memory, however, the stability of polarization reaction between the ferroelectric substance constituting the capacitor and the electrode determines the quality, so that it is necessary to increase the electrode area while securing polarization reaction (polarization should not decrease very much), rather than merely increasing the capacitor area. In the present embodiment, the contact connection section does not have step difference, so that electric characteristics deterioration of the ferroelectric substance due to a step difference is not generated. Therefore a memory with stable operation can be created with a miniaturized structure.

The present invention is not limited to the above described and illustrated embodiment, but can be modified in various ways. For example, for the transistors other than the ferroelectric capacitor, those with various structures which have been used conventionally can be used. The dimensions and the material of the ferroelectric capacitor, and the materials of the inter-layer insulation, metal plug and metal wiring are not limited to those mentioned in the foregoing description.

This application is based on a Japanese Patent Application No. 2005-262540 filed on Sep. 9, 2005, and the entire disclosure thereof is incorporated herein by reference.

What is claimed is:

1. A manufacturing method for a semiconductor memory having a ferroelectric capacitor as a storage element, comprising:
forming a circuit, other than the storage element, on a substrate;
forming an inter-layer insulation film over the circuit;
forming a contact hole which penetrates the inter-layer insulation film and reaches the circuit formed on the substrate;
filling the contact hole with a metal material to form a metal plug for inter-layer connection;
removing a surface of the inter-layer insulation film by a predetermined thickness so that an upper end portion of the metal plug protrudes from a surface of the inter-layer insulation film by a predetermined length;
forming a first metal film on an entire surface of the inter-layer insulation film and the metal plug protruding from the inter-layer insulation film, the first metal film becoming a lower electrode of the ferroelectric capacitor;
forming a ferroelectric film on a surface of the first metal film, the ferroelectric film becoming a dielectric of the ferroelectric capacitor;
forming a second metal film on a surface of the ferroelectric film, the second metal film becoming an upper electrode of the ferroelectric capacitor; and
forming the ferroelectric capacitor by pattering the second metal film, the ferroelectric film and the first metal film by batch etching.

2. The manufacturing method for a semiconductor memory according to claim 1, wherein said removing a surface of the inter-layer insulation film is performed such that a thickness of the inter-layer insulation film is reduced to ½ of a diameter of the metal plug or more.

3. The manufacturing method for a semiconductor memory according to claim 1, wherein said removing a surface of the inter-layer insulation film is performed by etching.

4. The manufacturing method for a semiconductor memory according to claim 1, wherein the first metal film includes platinum.

5. The manufacturing method for a semiconductor memory according to claim 4, wherein the second metal film includes platinum.

6. The manufacturing method for a semiconductor memory according to claim 1 further comprising forming a TiN layer on a wall of the contact hole before filling the contact hole with a metal material.

7. The manufacturing method for a semiconductor memory according to claim 1, wherein the metal material is tungsten.

8. The manufacturing method for a semiconductor memory according to claim 1, wherein alignment between the ferroelectric capacitor and the metal plug is accomplished by self alignment.

9. The manufacturing method for a semiconductor memory according to claim 1, wherein a protruding portion of the metal plug has a same diameter as a remaining portion of the metal plug.
